(19) United States
(12) Patent Application Publication
(10) Pub. No.: US 2012/0211788 A1
(43) Pub. Date: Aug. 23, 2012

(54) SEMICONDUCTOR LIGHT-EMITTING DEVICE

(76) Inventors: Hwan Kuk Yuh, Gyeonggi-do (KR); Seong Min Moon, Gyeonggi-do (KR)

(21) Appl. No.: 13/399,752

(22) Filed: Feb. 17, 2012

(30) Foreign Application Priority Data
Feb. 22, 2011 (KR) 10-2011-0015607

(51) Int. Cl. H01L 33/22

(52) U.S. Cl. 257/98; 257/E33.06

(57) ABSTRACT

A semiconductor light-emitting device having high optical extraction efficiency is provided. The semiconductor light-emitting device includes a substrate on which an n-type semiconductor layer, an active layer, and a p-type semiconductor layer are formed sequentially; an n electrode formed in an exposed part of the n-type semiconductor layer by removing parts of the n-type semiconductor layer, the active layer, and the p-type semiconductor layer; a current spreading layer formed on the p-type semiconductor layer; a p electrode formed on the current spreading layer; and a current blocking layer formed between the p-type semiconductor layer and the current spreading layer to include a region corresponding to the p electrode.

### CROSS-REFERENCE TO RELATED APPLICATION(S)

The present application claims priority under 35 U.S.C. §119(a) of Korean Patent Application No. 10-2011-0015607, filed on Feb. 22, 2011, the disclosure of which is expressly incorporated by reference herein in its entirety.

### TECHNICAL FIELD OF THE INVENTION

The present invention relates generally to a semiconductor light-emitting device. More particularly, the present invention relates to a semiconductor light-emitting device for increasing light extraction efficiency.

### BACKGROUND OF THE INVENTION

A Light Emitting Diode (LED) produces light with a material in the device. By boding semiconductors using a diode such as light-emitting diode, the LED converts the energy to the light through electron/hole recombination and then emits the light. Such an LED is widely used as illumination, display device, and light source, and its development is accelerating further.

In particular, owing to commercialization of mobile phone keypad, side viewer, and camera flash using a GaN-based LED which is positively developed and used, general illuminations using the LED are under development. Its applications such as backlight unit of a large-scale TV, car headlight, and general illumination are advancing from a small portable product to a bigger product of high output, high efficiency, and reliability. Hence, the light source exhibiting properties required for the corresponding product is demanded.

One of disadvantages of a semiconductor LED is low luminous efficiency. The luminous efficacy is determined by the light generation efficiency and the light emission efficiency. Internal quantum efficiency of the LED is almost 100%, whereas external quantum efficiency outside the LED is quite low.

One of reasons of the low external quantum efficiency is that an electrode is disposed in a surface for emitting the generated light to the outside. An n electrode and a p electrode are disposed in an n-type semiconductor layer or a p-type semiconductor layer respectively. The electrode includes a bonding electrode for connecting to the eternal power source, and an electrode line for spreading the current over the semiconductor layer. Mostly, the electrode is made of an opaque conductive material on account of conductivity and cost.

Since the light generated in the LED is proportional to the carrier injection, it is highly likely that the LED produces the light in a region corresponding to the electrode. However, when the opaque electrode is disposed in the optical propagation surface, the electrode can absorb or reflect the light and thus the light can proceed back into the LED.

The light not escaping the surface of the LED can move into the device and be lost as heat. This can lower the external light extraction efficiency of the LED and shorten the lifespan of the LED by increasing the heat of the LED.

### SUMMARY OF THE INVENTION

To address the above-discussed deficiencies of the prior art, it is a primary aspect of the present invention to provide a semiconductor light-emitting device having high light extraction efficiency.

According to one aspect of the present invention, a semiconductor light-emitting device includes a substrate on which an n-type semiconductor layer, an active layer, and a p-type semiconductor layer are formed sequentially; an n electrode formed in an exposed part of the n-type semiconductor layer by removing parts of the n-type semiconductor layer, the active layer, and the p-type semiconductor layer; a current spreading layer formed on the p-type semiconductor layer; a p electrode formed on the current spreading layer; and a current blocking layer formed to include a region corresponding to the p electrode between the p-type semiconductor layer and the current spreading layer. The current blocking layer is formed asymmetrically based on a center of the p electrode.

The current blocking layer may be formed such that a region of greater current flow widens based on the center of the p electrode.

The current blocking layer may be formed such that a region of a shorter distance between the p electrode and the n electrode widens based on the center of the p electrode.

The p electrode may include a p electrode pad connected to an external power source, and a p electrode arm for distributing current. The center can be a longitudinal center line of the p electrode arm, and the current blocking layer may widen in a region close to the n electrode based on the center line. The n electrode may include an n electrode pad connected to an external power source, and an n electrode arm for distributing current, and the current blocking layer may widen in a region close to the n electrode pad based on the center line.

The p electrode may include a p electrode pad connected to an external power source, and a p electrode arm for distributing current. The center may be a longitudinal center line of the p electrode arm, and the current blocking layer may widen at a location close to the n electrode along a longitudinal direction of the p electrode arm. The n electrode may include an n electrode pad connected to an external power source, and an n electrode arm for distributing current, and the current blocking layer may widen at a location close to the n electrode pad along the longitudinal direction of the p electrode arm.

The n electrode and the p electrode may have a circular pad shape, and the current blocking layer may widens in a region of the greater current flow based on a line perpendicular to a line interlinking centers of the n electrode and the p electrode, the perpendicular line at the center of the p electrode.

The current blocking layer may include a material having a refractive index equal to greater than a refractive index of the p-type semiconductor layer. The current blocking layer may be a material having conductivity lower than the current spreading layer, or an insulator, and may include TiO₂.

In a top surface of the current blocking layer, a region excluding the region corresponding to the p electrode may be uneven or textured.

A side of the current blocking layer may be uneven or textured. The refractive index of the current blocking layer may be greater than the refractive index of the current spreading layer.

A width ratio of the p electrode and the current blocking layer may be greater than 1:3.

The current blocking layer may include a material having the refractive index different from the refractive index of the p-type semiconductor layer by 0.5 or less. In a bottom surface of the current blocking layer, a region excluding the region corresponding to the p electrode may be uneven or textured, or include ZrO₂.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 is a cross-sectional view of a semiconductor light-emitting device according to one exemplary embodiment of the present invention;

FIG. 2A is a plane view of a semiconductor light-emitting device according to another exemplary embodiment of the present invention;

FIG. 2B is a cross-sectional view taken along D-D′ of FIG. 2A;

FIG. 3 is a plane view of a semiconductor light-emitting device according to yet another exemplary embodiment of the present invention;

FIG. 4 is a plane view of a semiconductor light-emitting device according to still another exemplary embodiment of the present invention;

FIG. 5 is a plane view of a semiconductor light-emitting device according to a further exemplary embodiment of the present invention;

FIG. 6 is a plane view of a semiconductor light-emitting device according to a further exemplary embodiment of the present invention;

FIGS. 7A, 7B and 7C are diagrams of a method for manufacturing the semiconductor light-emitting device according to a further exemplary embodiment of the present invention;

FIG. 8A is a cross-sectional view of a semiconductor light-emitting device according to a further exemplary embodiment of the present invention;

FIG. 8B is a diagram of optical propagation in a current blocking layer, a current spreading layer, and a p electrode on a p-type semiconductor layer of FIG. 8A;

FIG. 9A is an enlarged view of the current blocking layer, the current spreading layer, and the p electrode on the p-type semiconductor layer in the semiconductor light-emitting device according to a further exemplary embodiment of the present invention;

FIG. 9B is a diagram of the optical propagation in FIG. 9A;

FIG. 10 is a diagram of the optical propagation in a current blocking layer, a current spreading layer, and a p electrode on a p-type semiconductor layer of a semiconductor light-emitting device according to a further exemplary embodiment of the present invention;

FIG. 11A is an enlarged view of a current blocking layer, a current spreading layer, and a p electrode on a p-type semiconductor layer in a semiconductor light-emitting device according to a further exemplary embodiment of the present invention;

FIG. 11B is a diagram of the optical propagation in FIG. 11A; and

FIG. 12 is an enlarged view of the current blocking layer, the current spreading layer, and the p electrode on the p-type semiconductor layer in the semiconductor light-emitting device according to a further exemplary embodiment of the present invention.

Throughout the drawings, like reference numerals will be understood to refer to like parts, components and structures.

### DETAILED DESCRIPTION OF THE INVENTION

Exemplary embodiments of the inventive concept will be described below in more detail with reference to the accompanying drawings. The invention concept may, however, be embodied in different forms and should not be construed as limited to the embodiments set forth herein. Rather, there embodiments are provided so that this disclosure will be thorough and complete, and will fully convey the scope of the inventive concept to those skill in the art. In the drawings, a component can have a particular pattern or a certain thickness for the clarity of illustration. It is noted that the present invention is not limited the particular pattern or the certain thickness.

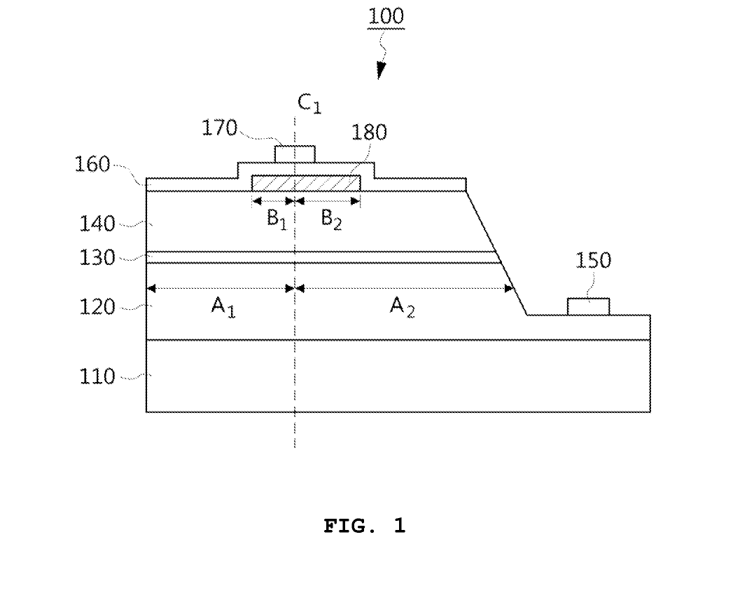

FIG. 1 is a cross-sectional view of a semiconductor light-emitting device according to one exemplary embodiment of the present invention. The semiconductor light-emitting device 100 includes a substrate 110 stacked with an n-type semiconductor layer 120, an active layer 130, and a p-type semiconductor layer 140 in a consecutive order, an n electrode 150 formed in an exposed part of the n-type semiconductor layer 120 by removing parts of the n-type semiconductor layer 120, the active layer 130, and the p-type semiconductor layer 140, a current spreading layer 160 formed on the p-type semiconductor layer 140, a p electrode 170 formed on the current spreading layer 160, and a current blocking layer 180 formed to include a region corresponding to the p electrode 170 between the p-type semiconductor layer 140 and the current spreading layer 160. The current blocking layer 180 is formed asymmetrically based on the center of the p electrode 170.

The n-type semiconductor layer 120, the active layer 130, and the p-type semiconductor layer 140 are sequentially staked on the substrate 110. The substrate 110 is a growth substrate for growing the n-type semiconductor layer 120, the active layer 130, and the p-type semiconductor layer 140, and can employ a nonconductive substrate such as sapphire or spinel MgAl₂O₄, or a conductive substrate such as SiC, Si, ZnO, GaAs, GaN and a metal substrate such as Ni or Cu. Among them, the sapphire substrate can be used in terms of the lattice constant matching with the semiconductor layer and the cost.

The n-type semiconductor layer 120 and the p-type semiconductor layer 140 can be made of semiconductors, for example, GaN-based semiconductor, ZnO-based semiconductor, GaAs-based semiconductor, GaP-based semiconductor, and GaAsP-based semiconductor, and can be realized as a p-type semiconductor layer and an n-type semiconductor layer respectively according to a doped impurity. The semiconductor layer can be formed using a well-known deposition method, for example, molecular beam epitaxy (MBE). Besides, the semiconductor layers can be properly selected from the group consisting of III-V-based semiconductor, II-VI-based semiconductor, and Si.

The impurity of the n-type semiconductor layer 120 can be selected from, for example, Si, Ge, and Sn. The impurity of the p-type semiconductor layer 140 can be selected from Mg, Zn and Be.

The active layer 130 actives the light emission. When the active layer 130 is made of a material having the energy band gap smaller than the energy band gaps of the n-type semiconductor layer 120 and the p-type semiconductor layer 140, an energy well is formed. When the n-type semiconductor layer 120 and the p-type semiconductor layer 140 are made of the GaN-based semiconductor, the active layer 130 can use InGaN-based compound semiconductor, AlGaN-based compound semiconductor, or AlInGaN-based compound semiconductor having the energy band gap lower than the energy band gap of the GaN-based semiconductor.

At this time, according to properties of the active layer 130, it is advantageous that the impurity is not doped. The wavelength or the quantum efficiency can be adjusted by modifying the height of the barrier, the thickness or the constitution of the energy well layer, or the number of the wells. For example, the depth of the energy well can be adjusted in the InGaN-based compound semiconductor and the AlGaN-based compound semiconductor by altering the contents of In and Al. A multi-quantum well structure can be constituted with two or more active layers, for example, with two or more InGaN layers and AlGaN layers.

The n electrode 150 interconnects the n-type semiconductor layer 120 to the external power source, and includes a conductive material such as metal, for example, Ti. The n electrode 150 is formed in the exposed part of the n-type semiconductor layer 120 by removing parts of the n-type semiconductor layer 120, the active layer 130, and the p-type semiconductor layer 140. When the substrate 110 is the nonconductive substrate such as sapphire substrate, the n-type semiconductor layer 120 is not exposed to the top. Parts of the n-type semiconductor layer 120, the active layer 130, and the p-type semiconductor layer 140 are removed, and thus the n electrode 150 can be formed in the exposed part of the n-type semiconductor layer 120.

The current spreading layer 160 formed on the p-type semiconductor layer 140 spreads current from the p electrode 170 connected to the external power source, over the p-type semiconductor layer 140. When the current is uniformly distributed over the p-type semiconductor layer 140 by means of the current spreading layer 160, the light can be uniformly produced also in the active layer 130 to thus increase the light generation efficiency. Since the current spreading layer 160 is disposed in the light extracting surface, it is advantageous that the current spreading layer 160 is made of a conductive and transparent material to diffuse the current. Preferably, the current spreading layer 160 includes, for example, Indium Tin Oxide (ITO).

The p electrode 170 is connected with the external power source to supply the power to the semiconductor light-emitting device 100, and implemented using a conductive material such as metal. For example, the p electrode 170 can use Pd, Au, Ni, or Cr. The p electrode 170 can include a single layer, or two or more layers for their functions. That is, when the p electrode 170 includes two or more layers, the layer formed on the p-type semiconductor layer 140 can be properly selected by considering compatibility, adhesion, or conductivity in relation with the p-type semiconductor layer 140 or the current spreading layer 160, and the outermost layer can be properly selected by considering the connection to the external power source.

While it is advantageous that the p electrode 170, which is disposed in the light extracting surface, is made of the transparent material for the optical extraction, an opaque conductive material is generally used because the conductivity is the most important function of the p electrode 170. Hence, of the light produced in the active layer 130, the light heading below the p electrode 170 cannot penetrate the p electrode 170 and can return to the light-emitting device. When the p electrode 170 is made of an opaque material of high optical absorption, the light is absorbed to the p electrode 170 without returning to the light-emitting device and thus the light can be lost. To avoid this, the current blocking layer 180 is formed below the p electrode 170 to include the region corresponding to the shape of the p electrode 170.

The current blocking layer 180 is formed on the p-type semiconductor layer 140, and blocks the current from flowing through the region corresponding to the p electrode 170 in the active layer 130. Since the current blocking layer 180 prevents the optical emission in the region below the p electrode 170 in the active layer 130, it blocks the light traveling below the p electrode 170 from being absorbed and lost. Hence, it is advantageous that the current blocking layer 180 is a material of conductivity lower than the current spreading layer 160, or an insulator, such that the current supplied from the p electrode 170 flows through the current spreading layer 160, not the current blocking layer 180. Also, it is advantageous that the current blocking layer 180 is made of a material of low optical absorption.

The current blocking layer 180 is formed asymmetrically based on a center of the p electrode 170. The current blocking layer 180 blocks the current flow from the p electrode 170 to the semiconductor light-emitting device 100. Thus, when the current is concentrated within the semiconductor light-emitting device 100, the asymmetrical current blocking layer 180 can be formed more in the current concentration region. Provided that the thickness of the current blocking layer 180 is constant, the wider part of the current blocking layer 180 from the base center line has the greater area and thus the current blocking layer 180 is formed more.

In FIG. 1, the center line C₁ is based on the center of the p electrode 170. It is assumed that the semiconductor light-emitting device 100 and the current blocking layer 180 are divided to regions A₁ and A₂, and regions B₁ and B₂ based on C₁. The current flows between the p electrode 170 and the n electrode 150, the current spreading layer 160 spreads and supplies the current throughout the p-type semiconductor layer 140. Yet, since the n electrode 150 is formed in the partially exposed part of the semiconductor light-emitting device 100, it is likely that the current flows through the region A₂.

That is, the current blocking layer 180 can have the wider region B₂ which is formed in the region A₂ of the greater current flow, based on the center of the p electrode 170. Provided that the heights of the regions B₁ and B₂ are the same, the region of the current blocking layer 180 formed in the region A₂ is wider. Accordingly, it is preferable to diffuse the current flow by forming the current blocking layer 180 more in the region A₂ of the greater current flow than the region A₁ of the lower current flow of the semiconductor light-emitting device 100.

Similarly, based on the center of the p electrode 170, the current blocking layer 180 can be formed to widen the region having a shorter distance between the p electrode 170 and the n electrode 150. That is, with respect to the distances between the region B₁ and the region B₂ of the current blocking layer 180 and the n electrode 150, the region B₁ is farther and the region B₂ is closer. Hence, the current is likely to concentrate in the region B₂ closer to the n electrode 150. The current concentration can be prevented by expanding the region B₂ closer to the n electrode 150.

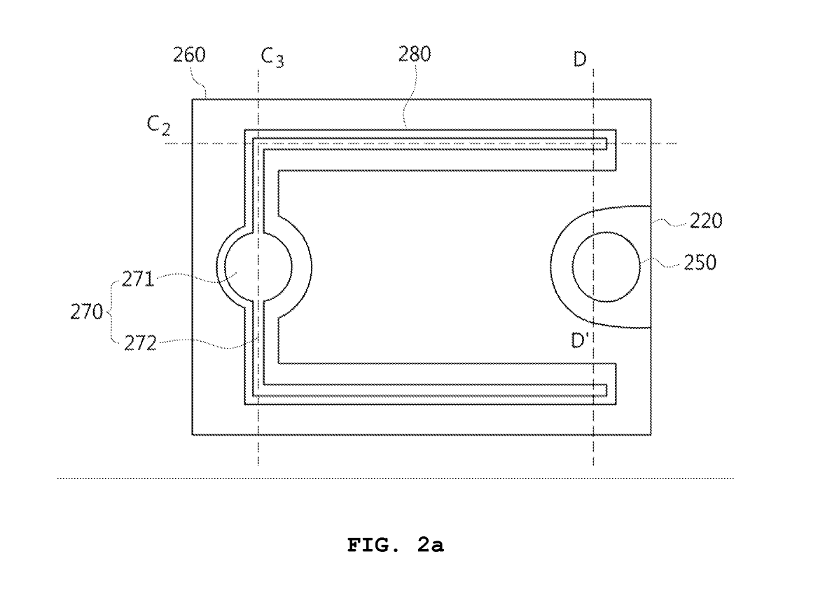

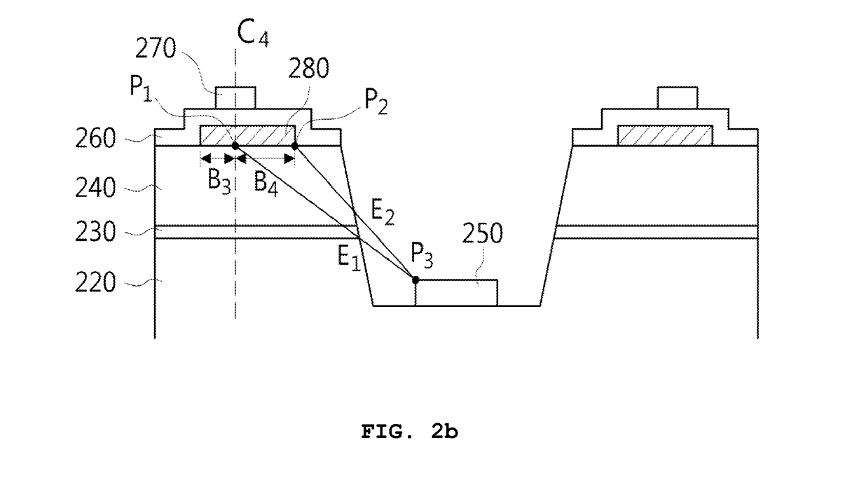

Now, further explanations are described by referring to FIGS. 2A through 6.

FIG. 2A is a plane view of a semiconductor light-emitting device according to another exemplary embodiment of the present invention, and FIG. 2B is a cross-sectional view taken along D-D′ of FIG. 2A. Hereafter, the same descriptions of an n-type semiconductor layer 220, an active layer 230, a p-type semiconductor layer 240, an n electrode 250, a current spreading layer 260, a p electrode 270, and a current blocking layer 280 as in FIG. 1 shall be omitted.

In FIG. 2A, the p electrode 270 includes a p electrode pad 271 connected to the external power source, and a p electrode arm 272 for distributing the current. The current spreading layer 260 is formed below the p electrode 270, and the current blocking layer 280 including the region of the p electrode 270 is formed under the current spreading layer 260. While the current blocking layer 280 is disposed above the current spreading layer 260 in FIG. 2A, the current blocking layer 280 is under the current spreading layer 260 and the current spreading layer 260 is transparent.

The p electrode arm 272 is formed in a line shape along an edge of the current spreading layer 260 formed on the p-type semiconductor layer 240. Yet, the shape of the p electrode arm 272 for distributing the current is not limited to the line. The n electrode 250 has a circular pad shape on the n-type semiconductor layer 220 exposed.

In FIG. 2A, the center of the p electrode 270 can include a longitudinal center line C₂ of the p electrode arm 272, and a vertical center line C₃ of the p electrode arm 272. Based on the center lines C₂ and C₃, the current blocking layer 280 widens in the region close to the n electrode 250. FIG. 2B is a cross-sectional view taken along D-D′. In FIG. 2B, a center line C₄ vertically crosses the semiconductor light-emitting device at the center line C₂. The current blocking current 280 is divided into a region B₃ and a region B₄ based on the center line C₄. To consider the distance to the n electrode 250, distances between a certain point P₃ of the n electrode 250 and points P₁ and P₂ closest to the n electrode 250 in the current blocking layer 280 are calculated. The distance between the certain point P₁ of the region B₃ and P₃ is E₁, the distance between the certain point P₂ of the region B₄ and P₃ is E₂, and E₁ is longer than E₂. Thus, the distance to the n electrode 250 in the region B₃ is longer than the distance to the n electrode 250 in the region B₄, and accordingly the region B₄ is wider than the region B₃.

Since the current blocking layer 280 is formed more in the region close to the n electrode 250 based on the center line C₄ of the p electrode 270, the current concentration can be prevented according to the relative location of the p electrode 270 and the n electrode 250.

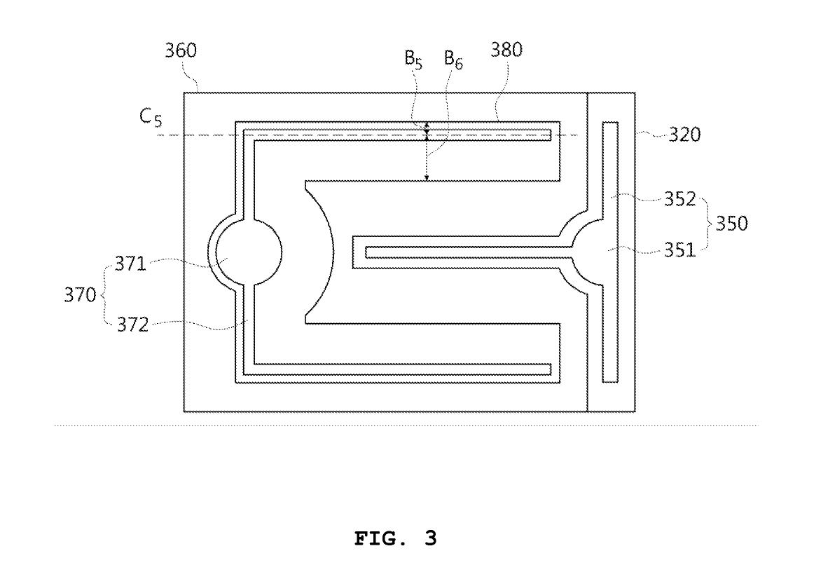

FIG. 3 is a plane view of a semiconductor light-emitting device according to yet another exemplary embodiment of the present invention. The same descriptions of an n-type semiconductor layer 320, an n electrode 350, a current spreading layer 360, a p electrode 370, a p electrode pad 371, a p electrode arm 372, and a current blocking layer 380 as in FIGS. 1, 2A, and 2B shall be omitted.

Unlike FIG. 2A, the n electrode 350 of FIG. 3 includes an n electrode pad 351 for connecting to the external power source, and an n electrode arm 352 for distributing the current. The n electrode pad 351 connected directly with the external power source. Since the n electrode arm 352 distributes the current, the current is more likely to concentrate in the region close to the n electrode pad 351, rather than the n electrode arm 352. Hence, when it is assumed that the current blocking layer 380 is divided into regions B₅ and B₆ based on a center line C₅ of the p electrode arm 372, the region B₆ close to the n electrode pad 351 can be wider.

Since the n electrode 350 includes the n electrode arm 352 separately from the n electrode pad 351, the n electrode arm 352 is formed to face the p electrode 370. Hence, the current concentration between the p electrode 370 and the n electrode 350 can increase, and it is advantageous that the region B₆ close to the n electrode 350 in the current blocking layer 380 in FIG. 3 is formed more than the region B₄ of FIG. 2A.

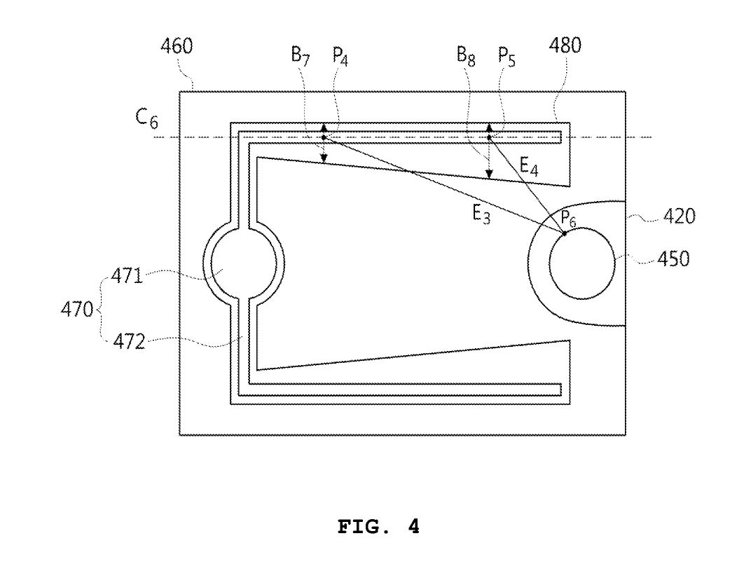

FIG. 4 is a plane view of a semiconductor light-emitting device according to still another exemplary embodiment of the present invention. The same descriptions of an n-type semiconductor layer 420, an n electrode 450, a current spreading layer 460, a p electrode 470, a p electrode pad 471, a p electrode arm 472, and a current blocking layer 480 as in FIGS. 1 through 3 shall be omitted.

In FIG. 4, the p electrode 470 includes the p electrode pad 471 connected to the external power source and the p electrode arm 472 for distributing the current. The p electrode arm 472 is formed in a line shape along the edge of the current spreading layer 460 formed on the p-type semiconductor layer 440. The n electrode 450 has a circular pad shape on the exposed n-type semiconductor layer 420.

When the center of the p electrode 470 is the longitudinal center line C₆ of the p electrode arm 472 in FIG. 4, the current blocking layer 470 widens along the longitudinal direction of the p electrode arm 472 based on the center line C₆ as approaching the n electrode 450.

For doing so, distances between certain points P₄ and P₅ of the center line C₆ and a certain point P₆ of the n electrode 450 are calculated. The distance between the points P₄ and P₆ is E₃, the distance between the points P₅ and P₆ is E₄, and E₃ is longer than E₄. Accordingly, the point P₅ is closer to the n electrode 450 than the point P₄, and the current blocking layer 480 at the point P₄ in the region B₇ is wider than the current blocking layer 480 at the point P₅ in the region B_{g}.

Based on the center line C₆, the current blocking layer 480 distant from the n electrode 450 is narrow, and the current blocking layer 480 close to the n electrode 450 is wide, that is, the current blocking layer 480 is formed more. Hence, the current concentration can be prevented far more effectively as the region close to the n electrode 450 is subject to the current concentration.

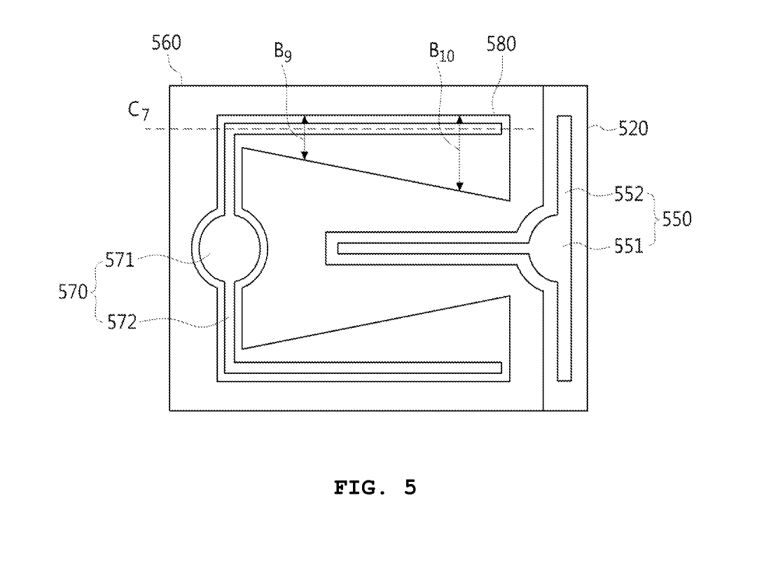

FIG. 5 is a plane view of a semiconductor light-emitting device according to a further exemplary embodiment of the present invention. The same descriptions on an n-type semiconductor layer 520, an n electrode 550, a current spreading layer 560, a p electrode 570, a p electrode pad 571, and a p electrode arm 572, and a current blocking layer 580 as in FIGS. 1 through 4 shall be omitted.

Unlike FIG. 4, the n electrode 550 of FIG. 5 includes an n electrode pad 551 for connecting to the external power source, and an n electrode arm 552 for distributing the current. The n electrode pad 551 is connected directly with the external power source. Since the n electrode arm 552 distributes the current, the current is more likely to concentrate in the region close to the n electrode pad 551, rather than the n electrode arm 552. Hence, with respect to regions B₉ and B₁₀ of the current blocking layer 580 along the longitudinal direction of the p electrode arm 572; that is, along a center line C₇, the region B₁₀ close to the n electrode pad 551 is wider than the region B₉ distant from the n electrode pad 551.

Since the n electrode 550 includes the n electrode arm 552 separately from the n electrode pad 551, the n electrode arm 552 is formed to face the p electrode 570. Hence, the current concentration between the p electrode 570 and the n electrode 550 can increase. It is advantageous that the region B₁₀ close to the n electrode pad 551 in the n electrode 550 including the n electrode arm of FIG. 5 is wider than the region B_{g} close to the n electrode pad 451 of FIG. 4 to form the current blocking layer 580 even more.

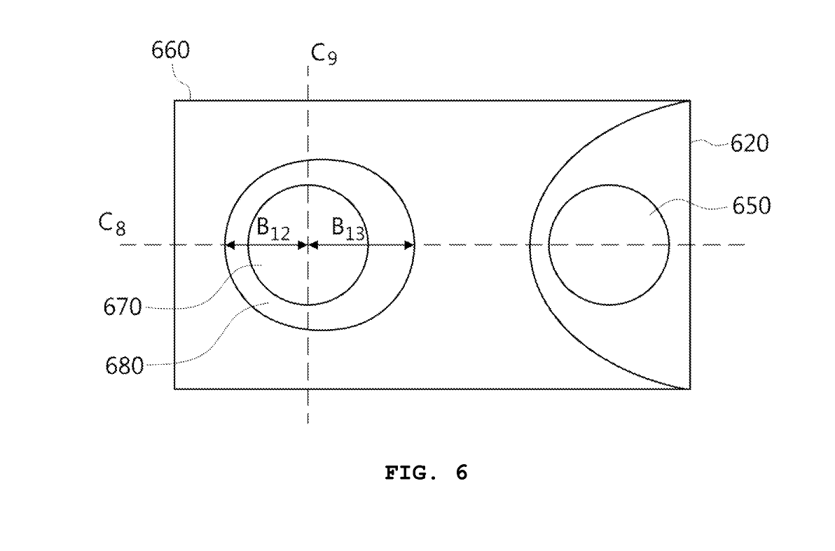

FIG. 6 is a plane view of a semiconductor light-emitting device according to a further exemplary embodiment of the present invention. The same descriptions on an n-type semiconductor layer 620, an n electrode 650, a current spreading layer 660, a p electrode 670, and a current blocking layer 680 as in FIGS. 1 through 5 shall be omitted.

In FIG. 6, both of the n electrode 650 and the p electrode 670 have the circular pad shape. When both of the electrodes are circular pads, the center line can be a line C₉ perpendicular to a center line C_{g} interlinking the center of the p electrode 670 and the center of the n electrode 650. Hence, the current blocking layer 680 is formed asymmetrically based on the center line C₉.

Since the current is likely to concentrate in the region B₁₃ close to the n electrode 650 based on the center line C₉ in the current blocking layer 680, the region B₁₃ is wider than the region B₁₂ distant from the n electrode 650.

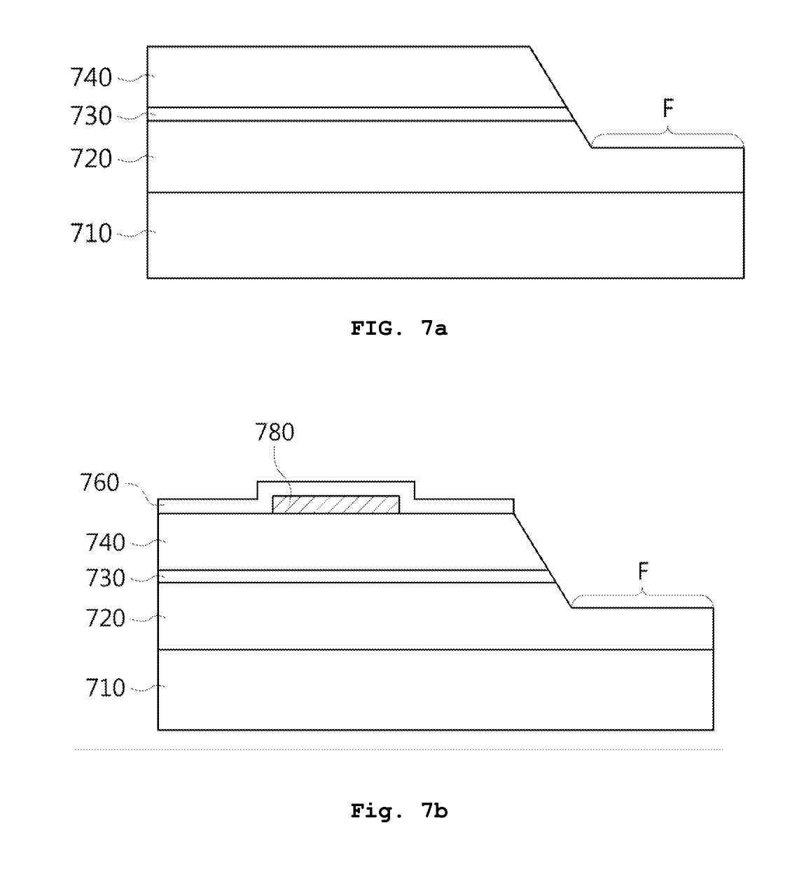

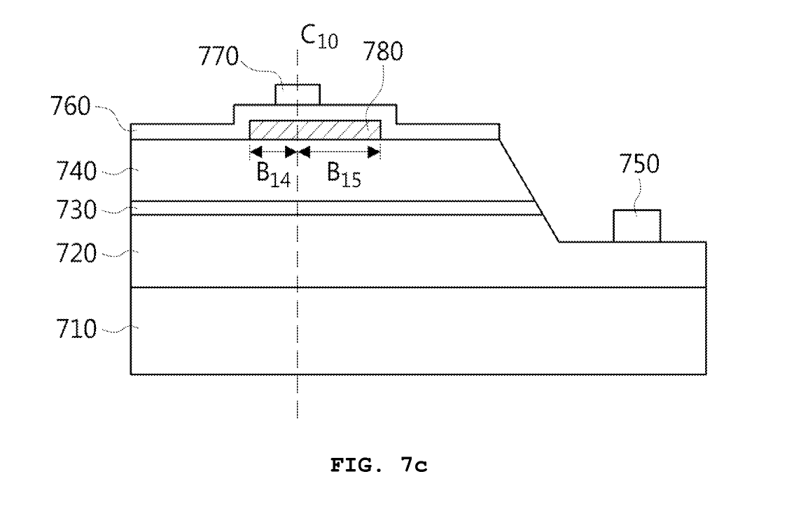

FIGS. 7A, 7B and 7C depict a method for manufacturing the semiconductor light-emitting device according to a further exemplary embodiment of the present invention. To fabricate the semiconductor light-emitting device, an n-type semiconductor layer 720, an active layer 730, and a p-type semiconductor layer 740 are sequentially stacked on a substrate 710, and part F of the n-type semiconductor layer 720 is exposed by removing parts of the n-type semiconductor layer 720, the active layer 730, and the p-type semiconductor layer 740 in FIG. 7A. After the growth, the n-type semiconductor layer 720, the active layer 730, and the p-type semiconductor layer 740 are mesa-etched to expose parts of them.

A current blocking layer 780 is formed on the p-type semiconductor layer 740, and a current spreading layer 760 is formed on the current blocking layer 780. The current blocking layer 780 is formed in a certain width asymmetrically based on the center of a p electrode 770 to form as shown in FIG. 7B.

An n electrode 750 is formed on the exposed part F of the n-type semiconductor layer 720, and the p electrode 770 is formed on the current spreading layer 760. The p electrode 770 is formed in light of the location of the current blocking layer 780 formed, such that regions B₁₄ and B₁₅ of the current blocking layer 780 are asymmetric based on the center line C₁₀.

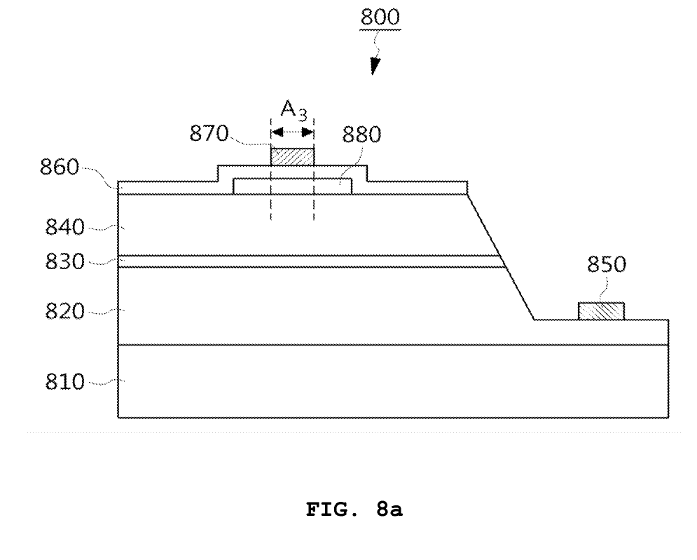

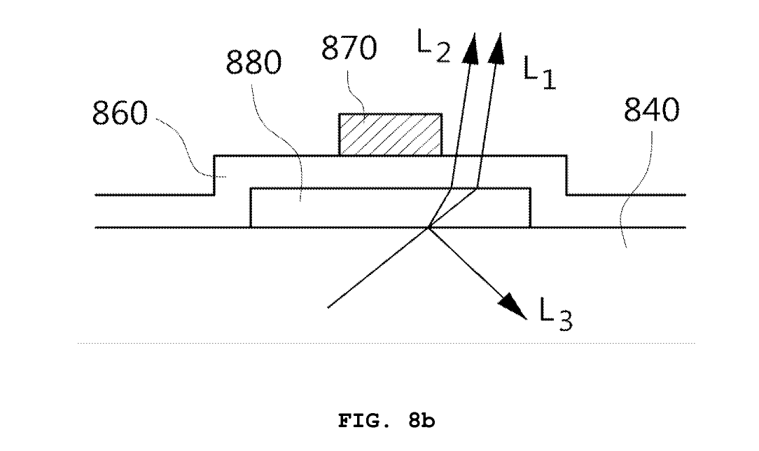

FIG. 8A is a cross-sectional view of a semiconductor light-emitting device according to a further exemplary embodiment of the present invention, and FIG. 8B depicts optical propagation in the current blocking layer, the current spreading layer, and the p electrode on the p-type semiconductor layer of FIG. 8A. Hereafter, the semiconductor light-emitting device is assumed to be, but not limited to, the GaN-based semiconductor light-emitting device.

The semiconductor light-emitting device 800 includes a substrate 810 including an n-GaN layer 820, an active layer 830, and a p-GaN layer 840 in sequence, an n electrode 850 formed in the exposed part of the n-GaN layer 820 by removing parts of the n-GaN layer 820, the active layer 830, and the p-GaN layer 840, a current spreading layer 860 formed on the p-GaN layer 840, a p electrode 870 formed on the current spreading layer 860, and a current blocking layer 880 formed between the p-GaN layer 840 and the current spreading layer 860 to include the region corresponding to the p electrode 870 and having refractive index equal to or greater than refractive index of the p-GaN layer 840.

The n-GaN layer 820 and the p-GaN layer 840 is GaN-based semiconductor and can be implemented using a p-GaN layer and an n-GaN layer according to their doped impurity. The impurity of the n-GaN layer 820 can be selected from, for example, Si, Ge, Se, Te, and C. The impurity of the p-GaN layer 840 can be selected from, for example, Mg, Zn, and Be.

The current blocking layer 880 is formed to include the region A₃ corresponding to the p electrode 870 between the p-GaN layer 840 and the current spreading layer 860. Since the current blocking layer 880 blocks the current applied from the p electrode 870, its conductivity should be lower than the p electrode 870. The current blocking layer 880 can be made of an insulator or a material of the low conductivity as much as possible. The current applied to the p electrode 870 cannot flow right under the p electrode 870 because of the current blocking layer 880 disposed below, and make a detour to some other region than the current blocking layer 880. That is, the current applied to the p electrode 870 is spread to the current spreading layer 870 beside the current blocking layer 880, and the current is supplied to the other regions excluding the p electrode 870.

When the current blocking layer 880 is conductive, it is advantageous that its conductivity is lower than the current spreading layer 860. When the conductivity of the current blocking layer 880 is higher than that of the current spreading layer 860, the light emission under the p electrode 870 is rather activated since the current applied to the p electrode 870 evades the current spreading layer 860 of the relatively low conductivity and proceeds to the current spreading layer 860.

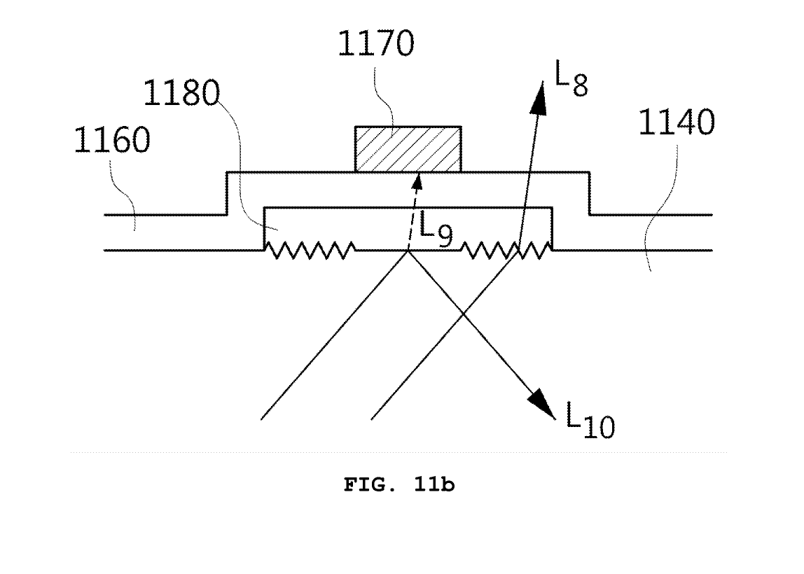

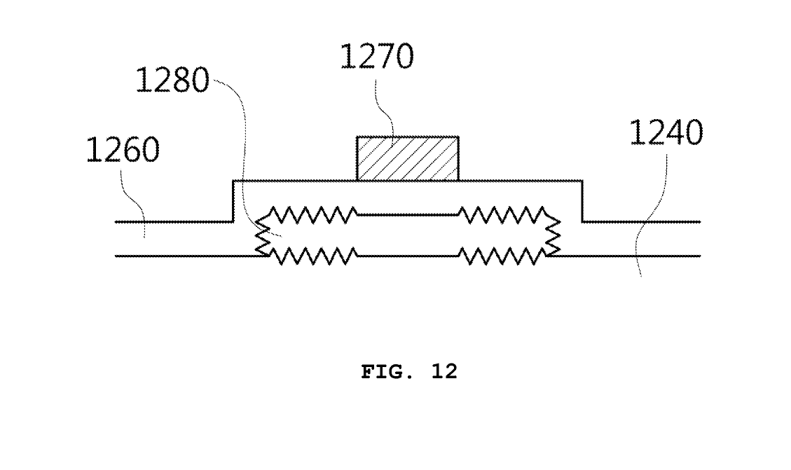

It is preferable that the current blocking layer 880 includes a material having the refractive index equal to or greater than the refractive index of the p-GaN layer 840 disposed below. FIG. 8B depicts the current blocking layer 880, the current spreading layer 860, and the p electrode 870 on the p-GaN layer 840. In FIG. 8B, when the light produced inside the semiconductor light-emitting device 800 passes through the p-GaN layer 840 and proceeds to the current blocking layer 880 and the refractive indexs of the p-GaN layer 840 and the current blocking layer 880 are the same, the light can pass through the current blocking layer 880 and the light L₁ can be exposed to the outside. Even when the refractive index of the current blocking layer 880 is greater than the refractive index of the p-GaN layer 840, total reflection does not occur according to Snell's law. Hence, the light is refracted in and passes through the current blocking layer 880, and the light L₂ can be extracted to the outside. When the refractive index of the current blocking layer 880 is not precisely the same as the refractive index of the p-GaN layer 840 but similar to the refractive index of the p-GaN layer 840, the critical angle for the total reflection is close to 90 degrees. Since the probability of the light incoming at the angle between the critical angle and 90 degrees is low, the optical extraction efficiency increases, which is further explained by referring to FIGS. 11A through 12.

However, when the refractive index of the current blocking layer 880 is smaller than the refractive index of the p-GaN layer 840 by great difference, the light L₃ is not extracted to the outside, totally reflected at the interface of the current blocking layer 880 and the p-GaN layer 840, and then returns into the semiconductor light-emitting device 800. While the returned light can be reflected in the device or extracted back to the outside after traveling, it can be lost after passing through the longer path than the light L₁ or L₂ or its intensity can be reduced. Thus, it is advantageous that the refractive index of the current blocking layer 880 is equal to or greater than the refractive index of the p-GaN layer 840 in terms of the increase of the light extraction efficiency and the maximum intensity.

The refractive index of GaN is about 2.5. Hence, preferably, the refractive index of the current blocking layer 880 is equal to or greater than 2.5. The material satisfying the condition of the current blocking layer 880 and having such a refractive index can include, for example, TiO₂.

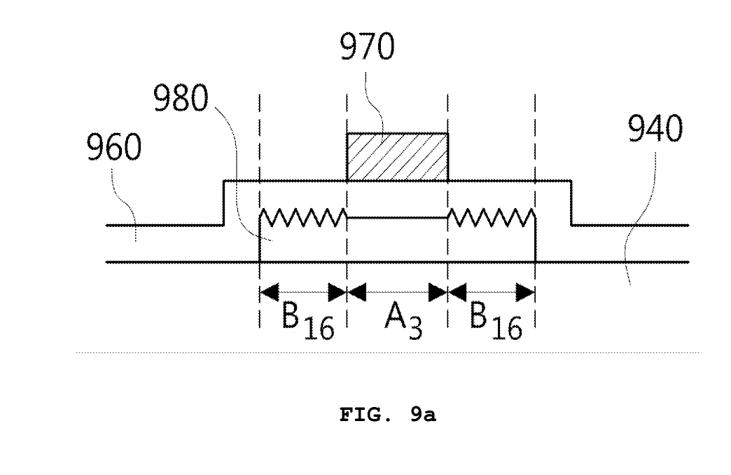

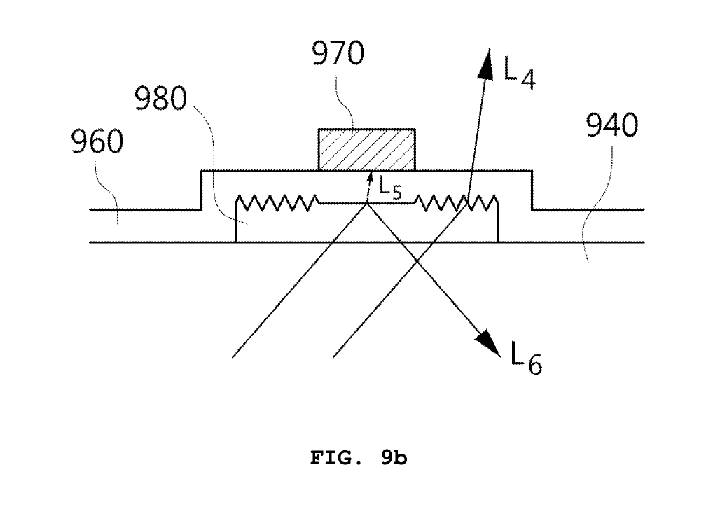

FIG. 9A is an enlarged view of the current blocking layer, the current spreading layer, and the p electrode on the p-GaN layer in the semiconductor light-emitting device according to a further exemplary embodiment of the present invention, and FIG. 9B depicts the optical propagation in FIG. 9A. Hereafter, the semiconductor light-emitting device is assumed to be, but not limited to, the GaN-based semiconductor light-emitting device.

The current blocking layer 980, the current spreading layer 960, and the p electrode 970 are formed on the p-GaN layer 940. In the current blocking layer 980, a region corresponding to the p electrode 970 is a region A₃ and a region excluding the region A₃ is a region B₁₆. In the top surface of the current blocking layer 980 of FIG. 9A, the surface of the region B₁₆ is textured or roughened. Compared to the smooth surface of the current blocking layer 880 of FIG. 8B, the uneven, textured, or rough surface of FIG. 9A increases the light extraction efficiency on account of the changed light path or incidence angle or the diffuse reflection. The uneven, textured, or rough surface of the current blocking layer 980 can be processed using the well-known method according to the material of the current blocking layer 980.

In FIG. 9B, when the light from the p-GaN layer 940 passes through the current blocking layer 980 and reaches the top surface of the current blocking layer 980, the light L₄ in the treated surface can be easily extracted to the outside. It is advantageous that the current blocking layer 980 does not treat the surface of the region A₃ corresponding to the p electrode 970. When the light reaching the surface corresponding to the region A₃ of the current blocking layer 980 from the p-GaN layer 940 proceeds, the light L₅ reaches the bottom of the p electrode 970. Since the p electrodes 970 can be made of the material for absorbing the light as mentioned earlier, the light L₅ can be lost. Hence, the probability of the light proceeding to the bottom of the p electrode 940 lowers when the surface of the region A₃ is not treated, the light L₆ can travel back into the device and be extracted to the outside without being absorbed by the p electrode 970.

When the refractive index of the current blocking layer 980 is greater than the refractive index of the current spreading layer 960, the light is subject to the total reflection at the interface of the current blocking layer 980 and the current spreading layer 960. In this case, it is more important to reduce the total reflection of the light and to increase the light extraction efficiency by treating the region for extracting the light in the surface of the current blocking layer 980. For example, when the current blocking layer 980 includes TiO₂ and the current spreading layer 960 includes ITO, the refractive index of TiO₂ is 2.5 and the refractive index of ITO is 2.0. Thus, the light extraction efficiency can be increased by treating the surface of the current blocking layer 980.

The width ratio of the p electrode 970 and the current blocking layer 980 can be properly selected by considering the size of the p electrode 970, the location of the p electrode 970, and the thickness or the performance of the current spreading layer 960. For example, the width ratio of the p electrode 970 and the current blocking layer 980 can be greater than 1:3. When the width ratio of the p electrode 970 and the current blocking layer 980 is smaller than 1:3, the width of the current blocking layer 980 is two small so that the current blocking layer 980 may not function well and the current can concentrate under the p electrode 970.

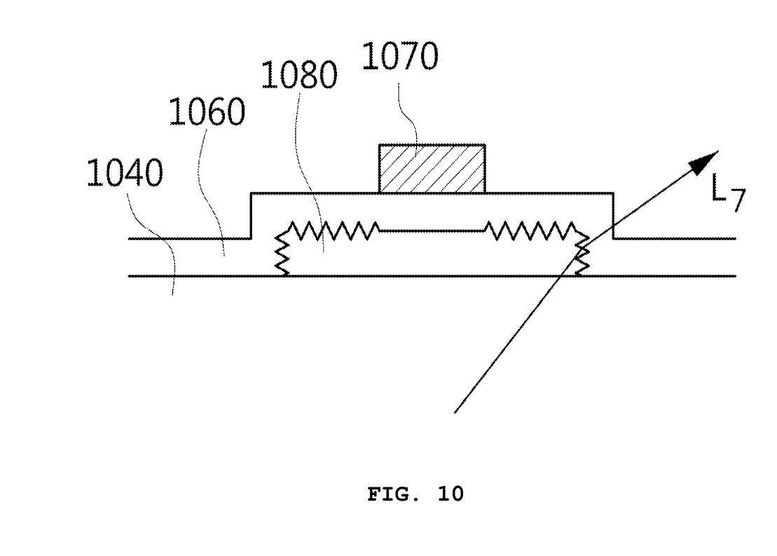

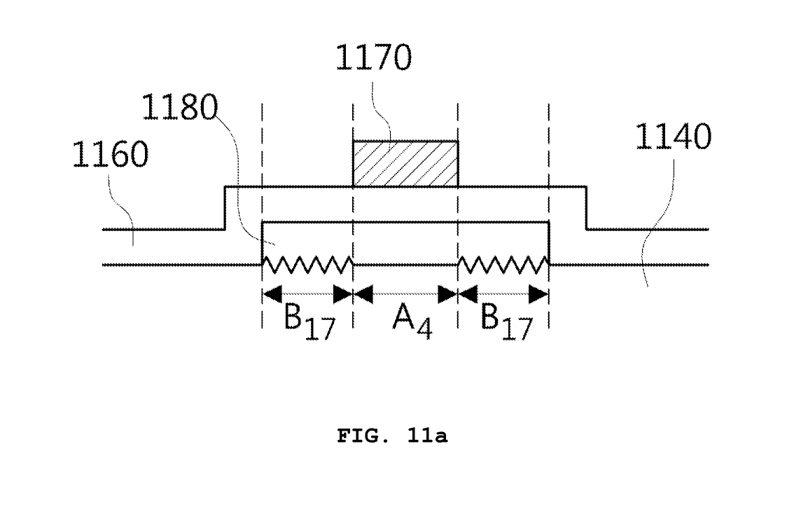

FIG. 10 depicts the optical propagation in a current blocking layer, a current spreading layer, and a p electrode on a p-GaN layer of the semiconductor light-emitting device according to a further exemplary embodiment of the present invention. Hereafter, the semiconductor light-emitting device is assumed to be, but not limited to, the GaN-based semiconductor light-emitting device.

Part of the top surface of the current blocking layer 980 of FIG. 9A is treated, and the side of the current blocking layer 1080 in FIG. 10 is treated as well. Hence, the light L₇ toward the side of the current blocking layer 1080 is likely to be exposed to the outside. When the width of the current blocking layer 1080 is relatively greater than the thickness, the light is likely to proceed to the top surface of the current blocking layer 1080 and thus only the top surface can be treated as shown in FIG. 9A. When the thickness of the current blocking layer 1080 is relatively greater than the width, it is preferable to treat only the side of the current blocking layer 1080 as shown in FIG. 10. Since it is most preferable to treat the surface of the entire region for extracting the light in the current blocking layer, it is most preferable to treat both of the top surface and the side as shown in FIG. 10.

Alternatively, the semiconductor light-emitting device includes a substrate including an n-GaN layer, an active layer, and a p-GaN layer in sequence, an n electrode formed in the exposed part of the n-GaN layer by removing parts of the n-GaN layer, the active layer, and the p-GaN layer, a current spreading layer formed on the p-GaN layer, a p electrode formed on the current spreading layer, and a current blocking layer formed between the p-GaN layer and the current spreading layer to include the region corresponding to the p electrode and having the refractive index different from the refractive index of the p-GaN layer by 0.5 or less. Hereafter, the semiconductor light-emitting device is assumed to be, but not limited to, the GaN-based semiconductor light-emitting device.

FIG. 11A is an enlarged view of a current blocking layer, a current spreading layer, and a p electrode on a p-GaN layer in a semiconductor light-emitting device according to a further exemplary embodiment of the present invention, and FIG. 11B depicts the optical propagation in FIG. 11A. The current blocking layer 1180 has the refractive index different from the refractive index of the p-GaN layer 1140 by 0.5 or less. That is, the refractive index of the current blocking layer 1180 is smaller than that of the p-GaN layer 1140. Since the refractive index of the p-GaN layer 1140 is 2.5, the refractive index of the current blocking layer 1180 ranges from 2.0 to 2.5.

When the current blocking layer 1180 is ZrO₂ with the refractive index 2.2, the critical angle is about 62 degrees. However, when SiO₂ of the similar insulation or optical absorption to ZrO₂ has the refractive index 1.5, the critical angle is 37 degrees. That is, when the current blocking layer 1180 is made of SiO₂ and the incidence angle exceeds 37 degrees, the light is subject to the total reflection and travels back into the device. As the light generates and travels in the active layer under the p-GaN layer 1140 under the current blocking layer 1180, the probability of the incidence angle exceeding 37 degrees is much higher than the probability of incidence angle exceeding 62 degrees even in consideration of the omnidirectional light generation.

When the refractive index of the current blocking layer 1180 is equal to or higher than the refractive index of the p-GaN layer 1140, the critical angle exceeds 90 degrees as stated earlier. Thus, every light passes through the interface without the total reflection. By contrast, since the refractive index of the current blocking layer 1180 is different from that of the p-GaN layer 1140 by 0.5 or less, part of the light is totally reflected and the other light passes, rather than the entire light totally reflected. Since the critical angle is about 62 degrees for ZrO₂, the light of the incidence angle between zero degree to 62 degrees passes through the interface and the light of the incidence angle between 62 degrees and 90 degrees is totally reflected.

When the refractive index of the current blocking layer 1180 is 2.0, the critical angle is about 53 degrees. Hence, when the refractive index difference from the p-GaN layer 1140 is maximum, the critical angle is about 53 degrees. About 60% of the total light 90% can be extracted without the total reflection, and thus the optical extraction efficiency can be enhanced.

Of the bottom surface of the current blocking layer 1180 of FIG. 11A, the region B₁₇ excluding the region A₄ corresponding to the p electrode 1170 can be treated. Thus, when the light of the incidence angle exceeding the critical angle travels, the light Lg can be diffusely reflected in the treated surface and extracted to the outside. That is, when the refractive index of the current blocking layer 1180 is 2.0 as stated above, the light of about 60% is extracted and the light of about 40% is totally reflected. By contrast, when the bottom surface of the current blocking layer 1180 is treated as shown in FIG. 11A, the light of 40% to be totally reflected can be extracted to the outside. However, it is preferable not to treat the surface of the region A₄. If the region A₄ is treated, the light L₉ can reach the bottom of the p electrode 1170 and be absorbed. Thus, when the region A₄ is not treated, the light L₁₀ can be totally reflected, travel back into the device, and then be extracted to the outside.

FIG. 12 is an enlarged view of a current blocking layer 1280, a current spreading layer 1260, and a p electrode 1270 on a p-GaN layer 1240 in a semiconductor light-emitting device according to a further exemplary embodiment of the present invention. Hereafter, the semiconductor light-emitting device is assumed to be, but not limited to, the GaN-based semiconductor light-emitting device.

All of the top surface, the bottom surface, and the side of the current blocking layer 1280 are treated to thus maximize the optical extraction efficiency in FIG. 12. Hence, it is easy to extract the light proceeding to the current blocking layer 1280 even at the interface of the p-GaN layer 1240 and at the interface of the current spreading layer 1260. Yet, of the top surface and the bottom surface of the current blocking layer 1280, the region corresponding to the p electrode 1270 are not treated to prevent the light from traveling below the p electrode 1270 and being absorbed.

So far, the semiconductor light-emitting device according to the exemplary embodiments has been explained in detail.

While the current blocking layer is asymmetrically formed based on the center of the p electrode by way of example, the current blocking layer can be formed symmetrically based on the center of the p electrode.

While the current blocking layer includes the material having the refractive index equal to or greater than the refractive index of the p-type semiconductor layer by way of example, the refractive index of the current blocking layer can be smaller than the refractive index of the p-type semiconductor layer.

While the semiconductor light-emitting device is the semiconductor light-emitting device having the horizontal structure, the present invention can be applied to a semiconductor light-emitting device having a vertical structure.

The semiconductor light-emitting device including the current blocking layer blocks the current from flowing below the electrode in the surface of the optical extraction so that the light is produced in other regions. Therefore, the optical absorption of the electrode can be prevented, the light flow back into the inside is prevented, and thus the optical extraction efficiency can be maximized.

By resolving the current concentration in the semiconductor light-emitting device, the uniform light emission distribution can improve the optical extraction and the reliability.

Further, since the surface for extracting the light in the current blocking layer is roughened, the light can be directly extracted to the top to thus minimize the optical path and to increase the total intensity.

While the invention has been shown and described with reference to certain exemplary embodiments thereof, it will be understood by those skilled in the art that various changes in form and details may be made therein without departing from the spirit and scope of the invention as defined by the appended claims and their equivalents.

What is claimed is:

1. A semiconductor light-emitting device comprising:
a substrate on which an n-type semiconductor layer, an active layer, and a p-type semiconductor layer are formed sequentially;
an n electrode formed in an exposed part of the n-type semiconductor layer by removing parts of the n-type semiconductor layer, the active layer, and the p-type semiconductor layer;
a current spreading layer formed on the p-type semiconductor layer;
a p electrode formed on the current spreading layer; and
a current blocking layer formed between the p-type semiconductor layer and the current spreading layer to comprise a region corresponding to the p electrode.

2. The semiconductor light-emitting device of claim 1, wherein the current blocking layer is formed asymmetrically based on a center of the p electrode.

3. The semiconductor light-emitting device of claim 2, wherein the current blocking layer is formed such that a region of greater current flow widens based on the center of the p electrode.

4. The semiconductor light-emitting device of claim 2, wherein the current blocking layer is formed such that a region of a shorter distance between the p electrode and the n electrode widens based on the center of the p electrode.

5. The semiconductor light-emitting device of claim 2, wherein the p electrode comprises a p electrode pad connected to an external power source, and a p electrode arm for distributing current.

6. The semiconductor light-emitting device of claim 5, wherein the center of the p electrode is a longitudinal center line of the p electrode arm, and
the current blocking layer widens in a region close to the n electrode based on the center line.

7. The semiconductor light-emitting device of claim 6, wherein the n electrode comprises an n electrode pad connected to an external power source, and an n electrode arm for distributing current, and
the current blocking layer widens in a region close to the n electrode pad based on the center line.

8. The semiconductor light-emitting device of claim 5, wherein the center of the p electrode is a longitudinal center line of the p electrode arm, and
the current blocking layer widens at a location close to the n electrode along a longitudinal direction of the p electrode arm.

9. The semiconductor light-emitting device of claim 8, wherein the n electrode comprises an n electrode pad connected to an external power source, and an n electrode arm for distributing current, and
the current blocking layer widens at a location close to the n electrode pad along the longitudinal direction of the p electrode arm.

10. The semiconductor light-emitting device of claim 2, wherein the n electrode and the p electrode have a circular pad shape, and
the current blocking layer widens in a region of the greater current flow based on a line perpendicular to a line interlinking centers of the n electrode and the p electrode, the perpendicular line at the center of the p electrode.

11. The semiconductor light-emitting device of claim 1, wherein the current blocking layer comprises a material having a refractive index equal to greater than a refractive index of the p-type semiconductor layer.

12. The semiconductor light-emitting device of claim 11, wherein the current blocking layer is a material having conductivity lower than the current spreading layer, or an insulator.

13. The semiconductor light-emitting device of claim 11, wherein the current blocking layer comprises TiO₂.

14. The semiconductor light-emitting device of claim 11, wherein, in a top surface of the current blocking layer, a region excluding the region corresponding to the p electrode is uneven or textured.

15. The semiconductor light-emitting device of claim 11, wherein a side of the current blocking layer is uneven or textured.

16. The semiconductor light-emitting device of claim 15, wherein the refractive index of the current blocking layer is greater than the refractive index of the current spreading layer.

17. The semiconductor light-emitting device of claim 11, wherein a width ratio of the p electrode and the current blocking layer is greater than 1:3.

18. The semiconductor light-emitting device of claim 1, wherein the current blocking layer comprises a material having the refractive index different from the refractive index of the p-type semiconductor layer by 0.5 or less.

19. The semiconductor light-emitting device of claim 18, wherein, in a bottom surface of the current blocking layer, a region excluding the region corresponding to the p electrode is uneven or textured.

20. The semiconductor light-emitting device of claim 18, wherein the current blocking layer comprises ZrO₂.
